(19) United States
(12) Patent Application Publication
(10) Pub. No.: US 2014/0027726 A1
(43) Pub. Date: Jan. 30, 2014

(54) ORGANIC LIGHT-EMITTING DISPLAY DEVICE AND METHOD OF MANUFACTURING THE SAME

(71) Applicant: SAMSUNG DISPLAY CO., LTD., Yongin-si (KR)

(72) Inventors: Jong-Hyun Choi, Yongin-si (KR); Dong-Seob Jeong, Yongin-si (KR); Yong-Duck Son, Yongin-si (KR); Jong-Ryuk Park, Yongin-si (KR)

(73) Assignee: SAMSUNG DISPLAY CO., LTD., Yongin-si (KR)

(21) Appl. No.: 13/745,687

(22) Filed: Jan. 18, 2013

(30) Foreign Application Priority Data
Jul. 30, 2012 (KR) 10-2012-0083516

(51) Int. Cl. H01L 51/52; H01L 33/08; H01L 51/56

(52) U.S. Cl. CPC H01L 51/5203; H01L 51/56; H01L 33/08
USPC 257/40; 438/34; 257/88

(57) ABSTRACT

An organic light-emitting display device having an improved manufacturing procedure and an improved emission efficiency, and a method of manufacturing the organic light-emitting display device.

### CROSS-REFERENCE TO RELATED PATENT APPLICATION

This application claims priority to and the benefit of Korean Patent Application No. 10-2012-0083516, filed on Jul. 30, 2012, in the Korean Intellectual Property Office, the disclosure of which is incorporated herein in its entirety by reference.

### BACKGROUND

1. Field

Aspects of embodiments according to the present invention relate to an organic light-emitting display device and a method of manufacturing the same.

2. Description of the Related Art

Flat panel display devices such as organic light-emitting display devices, liquid crystal display (LCD) devices, and the like are manufactured on a substrate on which a pattern, including a thin film transistor (TFT), a capacitor, and wiring for electrically connecting the TFT and the capacitor, is formed. In general, in order to form a minute pattern including a TFT or the like on a substrate having a flat panel display formed thereon, a pattern is transferred to an array substrate by using a mask on which the minute pattern is formed.

However, in a process of transferring the pattern by using the mask, first, it may be necessary to arrange the mask having a pattern formed thereon, and thus, as the number of processes using masks increases, manufacturing costs due to the masks also increase. Also, due to the aforementioned complicated processes, a manufacturing procedure becomes complicated and a manufacturing time increases, and thus, manufacturing costs increase.

### SUMMARY

Aspects of embodiments of the present invention provide an organic light-emitting display device having a simplified manufacturing procedure and improved emission efficiency, and a method of manufacturing the organic light-emitting display device.

According to an aspect of the present invention, there is provided an organic light-emitting display device including: a thin film transistor (TFT) including: an active layer on a substrate; a gate electrode insulated from the active layer and sequentially including a lower gate electrode and an upper gate electrode; and a source electrode and a drain electrode insulated from the gate electrode by an interlayer insulating layer, which is on the gate electrode, and contacting the active layer; a pad electrode including: a lower pad electrode on the interlayer insulating layer and on the same layer as the source electrode and the drain electrode; and an upper pad electrode on the lower pad electrode and electrically coupled to the TFT; and an organic light-emitting device electrically coupled to the TFT and including: a first organic light-emitting device in a first sub-pixel; a second organic light-emitting device in a second sub-pixel; and a third organic light-emitting device in a third sub-pixel, wherein the first organic light-emitting device sequentially includes: a first pixel electrode on the same layer as the lower gate electrode of the gate electrode; a first intermediate layer configured to emit light having a short wavelength; and an opposite electrode, wherein the second organic light-emitting device sequentially includes: a second pixel electrode, which includes a lower pixel electrode on the same layer as the lower gate electrode; and an upper pixel electrode on the same layer as the lower pad electrode; a second intermediate layer configured to emit light having a medium wavelength; and the opposite electrode, and wherein the third organic light-emitting device sequentially includes: a third pixel electrode on the interlayer insulating layer and on the same layer as the lower pad electrode; a third intermediate layer configured to emit light having a long wavelength; and the opposite electrode.

The lower gate electrode, the first pixel electrode, and the lower pixel electrode may each include a transparent conductive oxide (TOO).

The upper pad electrode, the upper pixel electrode, and the third pixel electrode may each include a transparent conductive oxide (TOO).

The first intermediate layer may be configured to emit blue light, the second intermediate layer may be configured to emit green light, and the third intermediate layer may be configured to emit red light.

A distance between the substrate and the third intermediate layer may be greater than a distance between the substrate and the first intermediate layer, or a distance between the substrate and the second intermediate layer.

The interlayer insulating layer may include an inorganic insulating material.

The source electrode, the drain electrode, and the lower pad electrode may each include a low-resistance metal material.

The organic light-emitting display device may further include a gate insulating layer between the active layer and the gate electrode, and the first organic light emitting device, the second light-emitting device, and the third organic light-emitting device may be on the gate insulating layer.

The organic light-emitting display device may further include a pixel-defining layer (PDL) that covers the TFT and the pad electrode, and the PDL may cover sides of the pad electrode and may expose at least a center region of the pad electrode.

The organic light-emitting display device may further include a capacitor that includes: a lower capacitor electrode on the same layer as the active layer; and an upper capacitor electrode on the same layer as the lower gate electrode, and may be electrically coupled to the TFT.

According to another aspect of the present invention, there is provided method of manufacturing an organic light-emitting display device, the method including: a first mask process of forming an active layer of a thin film transistor (TFT) on a substrate; a second mask process of forming a gate electrode including a lower gate electrode and an upper gate electrode, a first electrode pattern to form a first pixel electrode, and a second electrode pattern to form a second pixel electrode on the active layer; a third mask process of forming an interlayer insulating layer that includes contact holes that expose portions of the active layer, and openings that expose portions of the first electrode pattern and the second electrode pattern; a fourth mask process of forming a source electrode and a drain electrode that contact the active layer via the contact holes, the first pixel electrode, a lower pixel electrode, and a lower pad electrode; a fifth mask process of forming an upper pixel electrode on the lower pixel electrode, forming an upper pad electrode on the lower pad electrode, and forming a third pixel electrode; and a sixth mask process of forming a pixel-defining layer (PDL) that exposes at least portions of the first pixel electrode, the upper pixel electrode, and the third pixel electrode.

The second mask process may include: sequentially stacking a first insulating layer, a first conductive layer, and a second conductive layer on the active layer; patterning the first conductive layer and the second conductive layer to form a gate electrode that includes: a lower gate electrode formed of the first conductive layer; and an upper gate electrode formed of the second conductive layer; and patterning the first conductive layer and the second conductive layer to form the first electrode pattern and the second electrode pattern.

The method may further include forming a source region and a drain region by doping the active layer with an impurity after the second mask process.

The third mask process may include: forming a second insulating layer on the gate electrode, the first electrode pattern, and the second electrode pattern; patterning the first insulating layer and the second insulating layer to form the contact holes that expose the portions of the active layer; and patterning the second insulating layer to form the openings that expose the portions of the first electrode pattern and the second electrode pattern.

The fourth mask process may include: forming a third conductive layer on the interlayer insulating layer; patterning the third conductive layer to form the source electrode and a drain electrode that contact the active layer via the contact holes, and the lower pad electrode; forming the first pixel electrode by removing a second conductive layer included in the first electrode pattern; and forming the lower pixel electrode by removing a second conductive layer included in the second electrode pattern.

The first mask process may further include forming a lower capacitor electrode on the same layer as the active layer on the substrate, the second mask process may further include forming a third electrode pattern to form an upper capacitor electrode on the lower capacitor electrode, and the fourth mask process may further include forming the upper capacitor electrode by removing the second conductive layer included in the third electrode pattern.

The method may further include: forming a fourth conductive layer on an entire surface of the substrate; and patterning the fourth conductive layer to form the upper pixel electrode on the lower pixel electrode, to form the upper pad electrode on the lower pad electrode, and to form the third pixel electrode.

The fifth mask process may include: forming a third insulating layer on an entire surface of the substrate; and patterning the third insulating layer to form the PDL that covers sides of the first pixel electrode, the upper pixel electrode, and the third pixel electrode, and exposes at least portions of the first pixel electrode, the upper pixel electrode, and the third pixel electrode.

The method may further include: forming a first intermediate layer for emitting blue light on the exposed first pixel electrode; forming a second intermediate layer for emitting green light on the exposed second pixel electrode; and forming a third intermediate layer for emitting red light on the exposed third pixel electrode.

The method may further include forming an opposite electrode on an entire surface of the substrate to cover the first intermediate layer, the second intermediate layer, and the third intermediate layer.

### BRIEF DESCRIPTION OF THE DRAWINGS

The above and other features and aspects of the present invention will become more apparent by describing in detail exemplary embodiments thereof with reference to the attached drawings in which:

FIG. 1 is a plan view illustrating a structure of an organic light-emitting display device according to an embodiment of the present invention;

FIG. 2 is a cross-sectional view of the organic light-emitting display device of FIG. 1, taken along line II′-II′; and

FIGS. 3 through 15 are cross-sectional views illustrating a manufacturing procedure of the organic light-emitting display device of FIG. 2, according to an embodiment of the present invention.

### DETAILED DESCRIPTION

As the invention allows for various changes and numerous embodiments, exemplary embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed by the present invention. In the description, certain detailed explanations of related art may be omitted when it is deemed that they may unnecessarily obscure an aspect of the invention.

While such terms as “first,” “second,” etc., may be used to describe various components, such components must not be limited to the above terms. The above terms are used only to distinguish one component from another.

The terms used in the present specification are merely used to describe particular embodiments, and are not intended to limit the present invention. An expression used in the singular encompasses the expression in the plural, unless it has a clearly different meaning in the context. In the present specification, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

It will also be understood that when one element is referred to as being “coupled” (e.g., electrically coupled or connected) to another element, the one element may be directly coupled to the other element, or one or more intervening elements may be interposed therebetween. However, when one element is referred to as being “directly connected to”, or “directly coupled to” another element, an intervening third element may not be present. Also, as used herein, the term “and/or” includes any and all combinations of one or more of the associated listed items.

Hereinafter, the present invention will be described in detail by explaining exemplary embodiments of the invention with reference to the attached drawings.

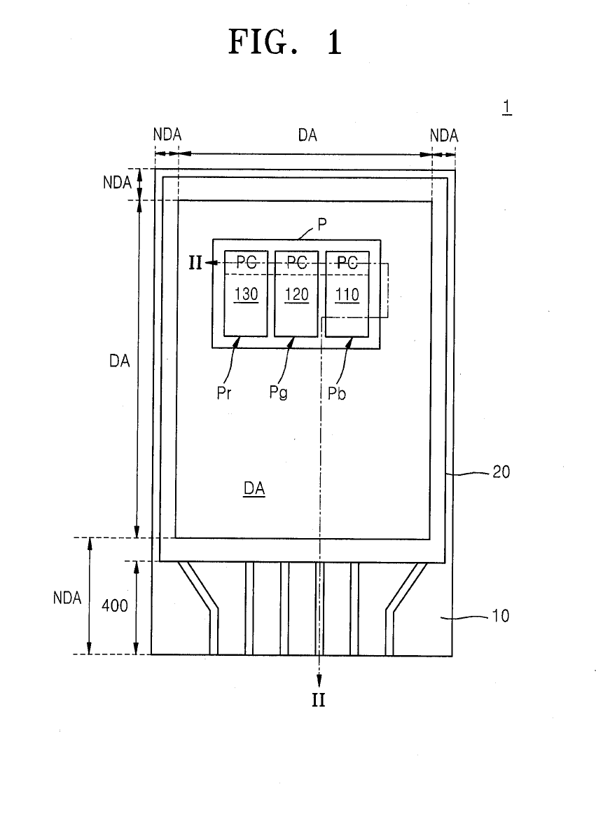

FIG. 1 is a plan view illustrating a structure of an organic light-emitting display device 1 according to an embodiment of the present invention. Referring to FIG. 1, the organic light-emitting display device 1 includes a first substrate 10 including a plurality of emission pixels P, and an encapsulation substrate 20 that is bonded to the first substrate 10 via a sealing process.

A thin film transistor (TFT), an organic light-emitting device, a capacitor, and the like may be formed on the first substrate 10. Also, the first substrate 10 may be a low-temperature poly-crystalline silicon (LTPS) substrate, a glass substrate, a plastic substrate, or the like.

The encapsulation substrate 20 is disposed on the first substrate 10 so as to block foreign moisture and air from reaching the emission pixels P arranged on the first substrate 10. The encapsulation substrate 20 may be positioned to face the first substrate 10. The encapsulation substrate 20 may be a glass substrate, a plastic substrate, or a Steel Use Stainless (SUS) substrate. The first substrate 10 and the encapsulation substrate 20 may be bonded to each other by using a sealing member (not shown) that may be disposed along their sides. However, aspects of the present invention are not limited thereto, and, instead of the encapsulation substrate 20, a thin encapsulation film may be formed on the first substrate 10 so as to protect the emission pixels P. The thin encapsulation film may have a structure in which an inorganic layer formed of silicon oxide or silicon nitride, and an organic layer formed of epoxy or polyimide are alternately stacked, but aspects of the present invention are not limited thereto.

The first substrate 10 includes a display area DA and a non-display area NDA at an outer region of the display area DA.

As described above, the emission pixels P are disposed in the display area DA of the first substrate 10. Each of the emission pixels P may be a unit pixel including a plurality of sub-pixels that emit different light colors. For example, an emission pixel P may be a unit pixel including a red sub-pixel Pr, a green sub-pixel Pg, and a blue sub-pixel Pb. However, aspects of the present invention are not limited thereto, and the emission pixel P may further include a white sub-pixel. Also, an array, a structure, and an area of the sub-pixels are not limited to the example of FIG. 1 and, thus, may vary.

The red, green, and blue sub-pixels Pr, Pg, and Pb may include emission regions 110, 120, and 130, and circuit regions PC, respectively. The emission regions 110, 120, and 130 include organic light-emitting devices. The circuit regions PC may include TFTs and capacitors, wherein the TFTs may be coupled to the organic light-emitting devices and, thus, drive the organic light-emitting devices, respectively, and the capacitors may be electrically connected to the TFTs. As illustrated in FIG. 1, the emission regions 110, 120, and 130, and the circuit regions PC may be disposed in parallel on a planar surface. However, aspects of the present invention are not limited thereto, and they may overlap with each other.

In the display area DA, a wire that is coupled to the TFTs and the capacitor may be formed. In the non-display area NDA, a pad region 400 that includes a pad electrode extending from the wire of the display area DA is formed.

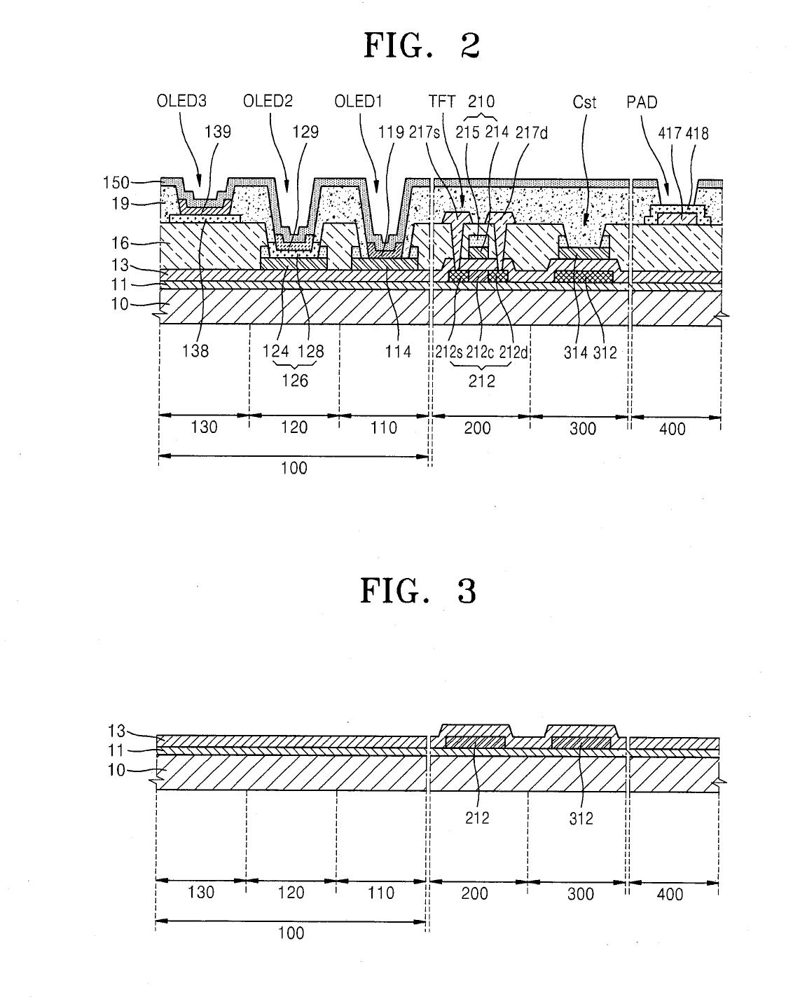

FIG. 2 is a cross-sectional view of the organic light-emitting display device 1 of FIG. 1, taken along line II-II′.

Referring to FIG. 2, the organic light-emitting display device 1 includes an emission region 100 for emitting red, green, and blue colors, a TFT region 200, a storage region 300, and the pad region 400. Here, the red, green, and blue sub-pixels Pr, Pg, and Pb are different from each other primarily in their features related to the emission region 100, and have the same features with respect to the TFT region 200 and the storage region 300. Thus, hereinafter, only the TFT region 200 and the storage region 300 included in the blue sub-pixel Pb will be described in detail, and descriptions of the TFT region 200 and the storage region 300 included in the red sub-pixel Pr and the green sub-pixel Pg are given by way of reference thereto.

The TFT region 200 has a TFT as a driving device. The TFT is formed of an active layer 212, a gate electrode 210, a source electrode 217s, and a drain electrode 217d. The gate electrode 210 may be formed of a lower gate electrode 214 and an upper gate electrode 215 on the lower gate electrode 214, wherein the lower gate electrode 214 may be formed of a transparent conductive oxide (TCO). The upper gate electrode 215 may be formed of a low-resistance metal material. A first insulating layer 13 that is a gate insulating layer is interposed between the gate electrode 210 and the active layer 212 so as to insulate the gate electrode 210 from the active layer 212. Also, a source region 212s and a drain region 212d, which may be highly doped with an impurity, are formed at both sides of the active layer 212, and the source region 212s and a drain region 212d are coupled to the source electrode 217s and the drain electrode 217d, respectively.

The storage region 300 may have a capacitor Cst. The capacitor Cst is electrically connected to the TFT and stores a signal that is applied to the TFT. The capacitor Cst may be formed of a lower capacitor electrode 312 and an upper capacitor electrode 314, and the first insulating layer 13 may be interposed as a dielectric layer therebetween. Here, the lower capacitor electrode 312 may be formed from the same layer as the active layer 212 of the TFT. The lower capacitor electrode 312 may be formed of a semiconductor material and may be doped with an impurity, thereby having increased electrical conductivity. The upper capacitor electrode 314 may be formed on the same layer as the lower gate electrode 214 of the TFT.

The emission region 100 has an organic light-emitting device OLED. The organic light-emitting device OLED emits light in response to a current that is applied to a pixel electrode. The organic light-emitting device OLED is formed of the pixel electrode that is electrically coupled to the TFT, an opposite electrode 150 that faces the pixel electrode, and an intermediate layer that is interposed therebetween and emits light.

The organic light-emitting device OLED may have an optical path length or thickness that varies in each of the red, green, and blue sub-pixels Pr, Pg, and Pb (refer to FIG. 1) that emit different light colors. Here, the optical path length or thickness indicates a thickness of each of organic layers, an electrode, and insulating layers, which are disposed in a path via which light from an EML is externally emitted. In a bottom emission type organic light-emitting display device, a plurality of layers having different refractive indexes included in the optical path may function as a Distributed Brag Reflector (DBR), so that a luminescent efficiency of light emitted from an OLED may be improved. In order to form an optical resonance structure, the optical path length or thickness may be calculated according to a length of an optical wavelength.

For example, an optical path length or thickness of a third organic light-emitting device OLED3 included in the emission region 130 of the red sub-pixel Pr (refer to FIG. 1) may have the greatest value, and an optical path length or thickness of a first organic light-emitting device OLED1 included in the emission region 110 of the blue sub-pixel Pb (refer to FIG. 1) may have the smallest value. An optical path length or thickness of a second organic light-emitting device OLED2 included in the emission region 120 of the green sub-pixel Pg (refer to FIG. 1) may have a medium value. Because red light has the longest wavelength, when the optical path length or thickness of the third organic light-emitting device OLED3 is increased to match with the longest wavelength, a luminescent efficiency may be improved due to a resonance effect. Similarly, because blue light has the shortest wavelength, when the optical path length or thickness of the first organic light-emitting device OLED1 is decreased to match with the shortest wavelength, a luminescent efficiency may be improved due to a resonance effect. Here, the wavelength or a thickness of the organic light-emitting device OLED is a relative concept, and thus, this means that the wavelength emitted from the red sub-pixel Pr is relatively long, compared to those emitted from the green and blue sub-pixels Pg and Pb, and the thickness of the third organic light-emitting device OLED3 is relatively thick, compared to those of the first and second organic light-emitting devices OLED1 and OLED2.

According to the present embodiment, a first pixel electrode 114 of the first organic light-emitting device OLED1 included in the blue sub-pixel Pb (refer to FIG. 1) is arranged on the first insulating layer 13 and may be formed from the same material layer as the lower gate electrode 214. A second pixel electrode 126 of the second organic light-emitting device OLED2 included in the green sub-pixel Pg (refer to FIG. 1) may include a lower pixel electrode 124 that is formed of the same material and on the same layer as the first pixel electrode 114, and an upper pixel electrode 128 that is formed on the lower pixel electrode 124. Thus, the optical path length or thickness of the second organic light-emitting device OLED2 is greater than the optical path length or thickness of the first organic light-emitting device OLED1. A third pixel electrode 138 of the third organic light-emitting device OLED3 included in the red sub-pixel Pr (refer to FIG. 1) may be formed on an interlayer insulating layer 16 that is formed on the first insulating layer 13. The third pixel electrode 138 may be formed from the same material layer as the upper pixel electrode 128. Thus, due to a thickness of the interlayer insulating layer 16 below the third pixel electrode 138, the optical path length or thickness of the third organic light-emitting device OLED3 is greater than the thickness of the second organic light-emitting device OLED2. As described above, according to the present embodiment, an optical path length or thickness of an organic light-emitting device varies in each of the sub-pixels due to a pixel electrode and an insulating layer below the pixel electrode. By doing so, the number of manufacturing processes of the organic light-emitting display device 1 is decreased.

The pad region 400 includes a pad electrode PAD. Although not illustrated, the pad electrode PAD may be electrically coupled to the TFT, the capacitor Cst, or the organic light-emitting device via a wire (not shown). Also, the pad electrode PAD may be electrically connected to a driver integrated circuit (IC) (not shown) that supplies a current to drive the organic light-emitting display device 1. Thus, the pad electrode PAD may receive the current, a voltage, or a signal from the driver IC and then deliver the current, a voltage, or a signal to the TFT, the capacitor Cst, or the organic light-emitting device in the display area DA (refer to FIG. 1) via the wire. In order to be electrically connected to the driver IC (not shown) outside, at least a portion of the pad electrode PAD may be exposed via an opening of a pixel-defining layer (PDL) 19.

In FIG. 2, the pad electrode PAD includes a lower pad electrode 417 that is formed on the interlayer insulating layer 16, and an upper pad electrode 418 that is formed on the lower pad electrode 417. Here, the lower pad electrode 417 may be formed of the same material and on the same layer as the source electrode 217s and the drain electrode 217d. Thus, the lower pad electrode 417 may include the low-resistance metal material. The upper pad electrode 418 may be formed of the same material and on the same layer as the upper pixel electrode 128 and the third pixel electrode 138. Thus, the upper pad electrode 418 may include the TCO.

According to the present embodiment, when the upper pad electrode 418 is formed, the third pixel electrode 138 and the upper pixel electrode 128 of the second pixel electrode 126 are simultaneously (or concurrently) formed. By doing so, forming the organic light-emitting device having an increased luminescent efficiency, and decreasing the number of manufacturing processes may be simultaneously (or concurrently) performed. This effect will be described in detail when a manufacturing procedure of the organic light-emitting display device 1 is described.

FIGS. 3 through 15 are cross-sectional views illustrating a manufacturing procedure of the organic light-emitting display device 1 of FIG. 2, according to an embodiment of the present invention. Hereinafter, the manufacturing procedure of the organic light-emitting display device 1 of FIG. 2 will be described.

First, as illustrated in FIG. 3, an auxiliary layer 11 is formed on the first substrate 10. In more detail, the first substrate 10 may be formed of a transparent glass material containing SiO₂ as a main component. However, the first substrate 10 is not limited thereto, and the first substrate 10 may be formed of various materials including a transparent plastic material, a metal material, or the like.

In order to prevent impurity ions from diffusing into a top surface of the first substrate 10, to prevent moisture or air from penetrating into the top surface of the first substrate 10, and to planarize the top surface of the first substrate 10, the auxiliary layer 11 such as a barrier layer, a blocking layer, and/or a buffer layer may be formed. The auxiliary layer 11 may be formed of SiO₂ and/or SiNₓ by using various deposition methods including a plasma-enhanced chemical vapor deposition (PECVD) method, an atmospheric pressure CVD (APCVD) method, a low pressure CVD (LPCVD) method, or the like.

Next, as illustrated in FIG. 3, the active layer 212 of the TFT and the lower capacitor electrode 312 are formed on the auxiliary layer 11. In more detail, an amorphous silicon layer (not shown) is first deposited on the auxiliary layer 11 and then is crystallized, so that a polycrystalline silicon layer (not shown) is formed. The amorphous silicon layer may be crystallized by using various methods including a rapid thermal annealing (RTA) method, a solid phase crystallization (SPC) method, an excimer laser annealing (ELA) method, a metal-induced crystallization (MIC) method, a metal-induced lateral crystallization (MILC) method, a sequential lateral solidification (SLS) method, and the like. The polycrystalline silicon layer may be patterned into the active layer 212 of the TFT and the lower capacitor electrode 312 via a mask process using a first mask (not shown).

In the present embodiment, the active layer 212 and the lower capacitor electrode 312 are separated but the active layer 212 and the lower capacitor electrode 312 may be integrally formed.

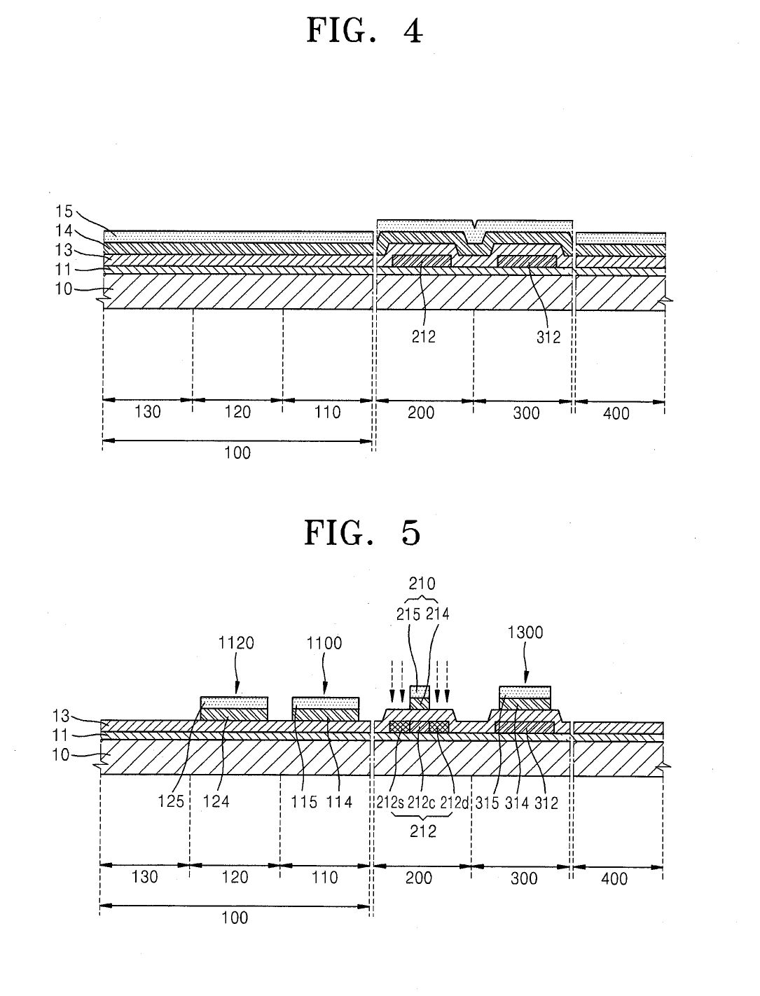

Next, as illustrated in FIG. 4, the first insulating layer 13, a first conductive layer 14, and a second conductive layer 15 are sequentially formed on a surface (e.g., an entire surface) of the first substrate 10 on which the active layer 212 and the lower capacitor electrode 312 are formed.

The first insulating layer 13 may be formed of an inorganic insulating material (including SiNₓ or SiO₂) by using various deposition methods including a PECVD method, an APCVD method, an LPCVD method, or the like. The first insulating layer 13 may be interposed between the active layer 212 of the TFT and the gate electrode 210 (refer to FIG. 2) and, thus, function as a gate insulating layer. Also, the first insulating layer 13 may be interposed between the upper capacitor electrode 314 and the lower capacitor electrode 312 (refer to FIG. 2) and, thus, function as a dielectric layer.

The first conductive layer 14 may include at least one transparent material selected from the group consisting of ITO, IZO, ZnO, AZO, GIZO, and In₂O₃. The first conductive layer 14 may be patterned into the first pixel electrode 114, the lower pixel electrode 124, the lower gate electrode 214, and the upper capacitor electrode 314. When the organic light-emitting display device 1 is a bottom emission type organic light-emitting display device that emits light toward a substrate, a pixel electrode is formed as a transparent electrode. Thus, the first conductive layer 14 to be formed as the pixel electrode may be formed of TCO.

The second conductive layer 15 may include at least one material selected from the group consisting of Ag, Mg, Al, Pt, Pd, Au, Ni, Nd, Ir, Cr, Li, Ca, Mo, Ti, W, MoW, and Cu. The second conductive layer 15 may have a three-layer structure of Mo—Al—Mo. The second conductive layer 15 may be patterned into the upper gate electrode 215. According to the present embodiment, the gate electrode 210 smoothly transmits a current; as such, the gate electrode 210 may not be formed by using only the first conductive layer 14 having large resistance. Thus, in order to allow the TFT to perform an appropriate function, the second conductive layer 15 may be formed of a low-resistance metal material having smaller resistance than the first conductive layer 14.

Referring to FIG. 5, a first electrode pattern 1100 to form the first pixel electrode 114, a second electrode pattern 1120 to form the second pixel electrode 126, and the gate electrode 210 are formed on the first substrate 10.

In more detail, the first conductive layer 14 and the second conductive layer 15, which are sequentially formed on the first substrate 10 may be patterned via a mask process using a second mask (not shown). By doing so, the gate electrode 210 that includes the lower gate electrode 214 formed from the first conductive layer 14, and the upper gate electrode 215 formed from the second conductive layer 15 is arranged in the TFT region 200. Also, in the emission region 110 for emitting a blue color, the first electrode pattern 1100 to form the first conductive layer 14 into the first pixel electrode 114 may be formed, and in the emission region 120 for emitting a green color, the second electrode pattern 1120 to form the first conductive layer 14 into the lower pixel electrode 124 of the second pixel electrode 126 may be formed. In the storage region 300, a third electrode pattern 1300 to form the first conductive layer 14 into the upper capacitor electrode 314 may be formed. In FIG. 5, reference numerals 115, 125, and 315 indicate that the second conductive layer 15 is patterned into each of the electrode patterns, and will be removed later.

Here, the gate electrode 210 corresponds to a center region of the active layer 212, and the active layer 212 is doped with an n-type impurity or a p-type impurity by using the gate electrode 210 as a self-aligned mask, so that the source region 212s and the drain region 212d are formed at sides of the active layer 212, which correspond to both side portions of the gate electrode 210, and a channel region 212c is formed between the source region 212s and the drain region 212d. Here, the impurity may be boron (B) ions or phosphorous (P) ions.

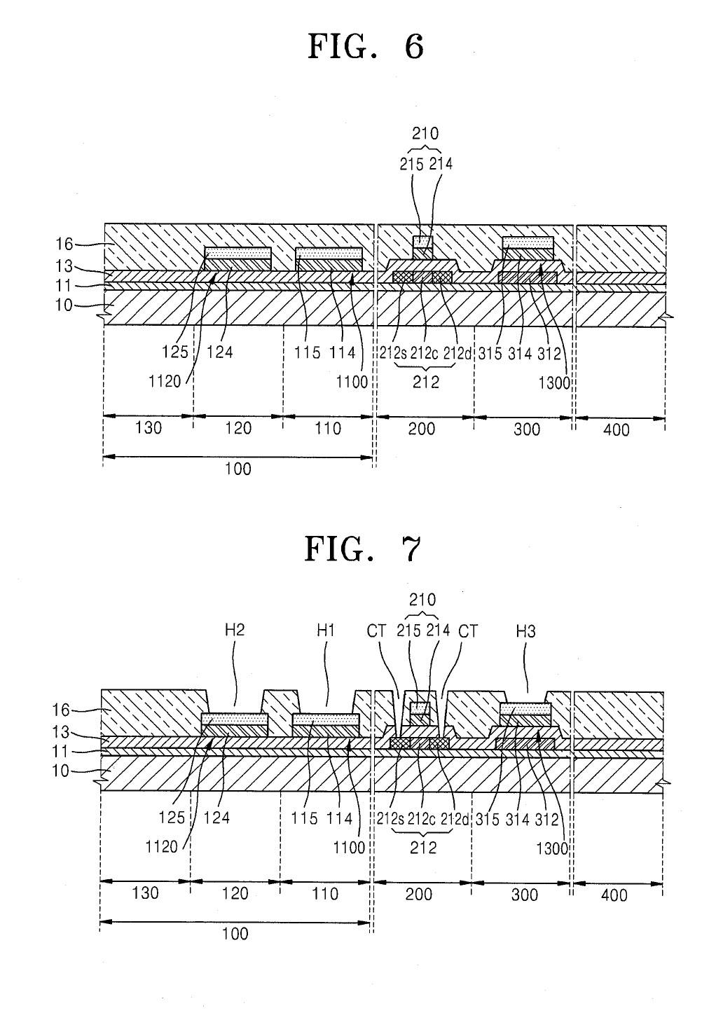

Next, as illustrated in FIG. 6, a second insulating layer 16 is deposited on the first substrate 10 on which the gate electrode 210 is formed.

The second insulating layer 16 may be formed of an inorganic insulating material including SiNₓ or SiO₂, by using various deposition methods including a PECVD method, an APCVD method, an LPCVD method, or the like. The second insulating layer 16 may have a suitable (or sufficient) thickness. For example, the thickness of the second insulating layer 16 may be greater than a thickness of the first insulating layer 13, so that the second insulating layer 16 may function as the interlayer insulating layer 16 between the gate electrode 210 of the TFT and the source electrode 217s and between the gate electrode 210 of the TFT and the drain electrode 217d. Also, the second insulating layer 16 may be formed of not only the inorganic insulating material but also formed by alternating an inorganic insulating material and at least one organic insulating material selected from the group consisting of polyimide, polyamide, acryl resin, benzocyclobutene, and phenol resin.

Next, as illustrated in FIG. 7, the second insulating layer 16 is patterned to form the interlayer insulating layer 16 having openings H1, H2, and H3 that expose the first electrode pattern 1100, the second electrode pattern 1120, and the third electrode pattern 1300, respectively, and contact holes CT that expose portions of the source region 212s and the drain region 212d of the active layer 212, respectively.

In more detail, the interlayer insulating layer 16 may be patterned via a mask process using a third mask (not shown) so that the openings H1, H2, and H3 and the contact holes CT are formed. Here, the contact holes CT expose portions of the source region 212s and the drain region 212d of the active layer 212, respectively, and the openings H1, H2, and H3 expose portions of the second conductive layer 15, which form upper portions of the first, second, and third electrode patterns 1100, 1120, and 1300.

As illustrated in FIG. 7, the opening H3, which is a third opening for exposing the upper capacitor electrode 314, may expose a portion of the upper capacitor electrode 314 and not side portions of the upper capacitor electrode 314. However, alternatively, the third opening H3 may completely expose the upper capacitor electrode 314. Also, aspects of the present invention are not limited thereto, and the third opening H3 may not be formed so that the upper capacitor electrode 314 is covered by the interlayer insulating layer 16 and thus is not exposed.

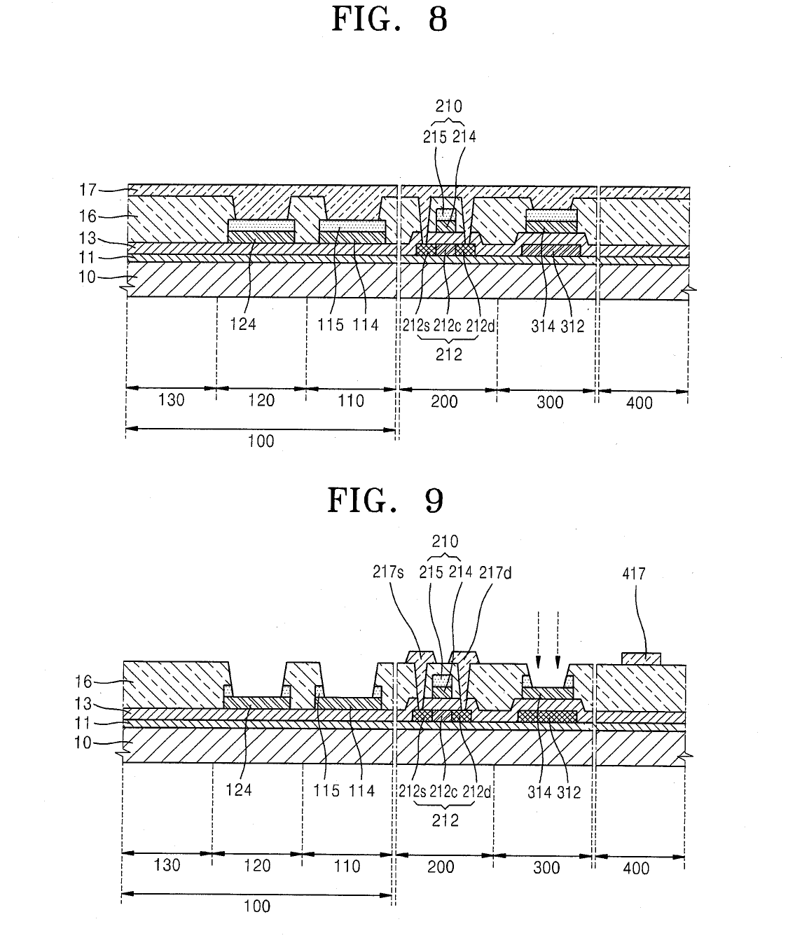

Next, as illustrated in FIG. 8, a third conductive layer 17 is completely deposited on the first substrate 10 so as to cover the interlayer insulating layer 16.

The third conductive layer 17 may be formed of the same low-resistance metal material as the second conductive layer 15. However, aspects of the present invention are not limited thereto, and third conductive layer 17 may be formed of various conductive materials. Also, the conductive materials are deposited to have a thickness sufficient to fill the openings H1, H2, and H3 and the contact holes CT.

Next, as illustrated in FIG. 9, the third conductive layer 17 (refer to FIG. 8) is patterned so that the source electrode 217s, the drain electrode 217d, the lower pad electrode 417, the first pixel electrode 114, and the lower pixel electrode 124 are formed.

In more detail, the third conductive layer 17 (refer to FIG. 8) may be patterned via a mask process using a fourth mask (not shown) so that the source electrode 217s and the drain electrode 217d are formed in the TFT region 200. Here, the source electrode 217s and the drain electrode 217d contact the source region 212s and the drain region 212d of the active layer 212, respectively, via the contact holes CT.

When the source electrode 217s and the drain electrode 217d are formed, simultaneously (or concurrently), the lower pad electrode 417 may be formed on the interlayer insulating layer 16 in the pad region 400.

When the source electrode 217s, the drain electrode 217d, and the lower pad electrode 417 are formed, simultaneously (or concurrently), the first pixel electrode 114 and the lower pixel electrode 124 may be formed. However, aspects of the present invention are not limited thereto, and the source electrode 217s, the drain electrode 217d, and the lower pad electrode 417 may be first formed and then the first pixel electrode 114 and the lower pixel electrode 124 may be formed via an additional etching process. In more detail, in the first electrode pattern 1100 (refer to FIG. 8), the second conductive layer 15 exposed via the first opening H1 may be removed so that the first pixel electrode 114 may be formed. Similarly, in the second electrode pattern 1120 (refer to FIG. 8), the second conductive layer 15 exposed via the second opening H2 may be removed so that the lower pixel electrode 124 may be formed. Thus, the lower gate electrode 214 and pixel electrodes are formed of the same material and on the same layer.

In the third electrode pattern 1300 (refer to FIG. 8), the second conductive layer 15 exposed via the third opening H3 is removed so that the upper capacitor electrode 314 is formed. Also, after the second conductive layer 15 forming the upper capacitor electrode 314 is removed, a process of doping the lower capacitor electrode 312 with an impurity may additionally be performed to further increase electrical conductivity of the lower capacitor electrode 312.

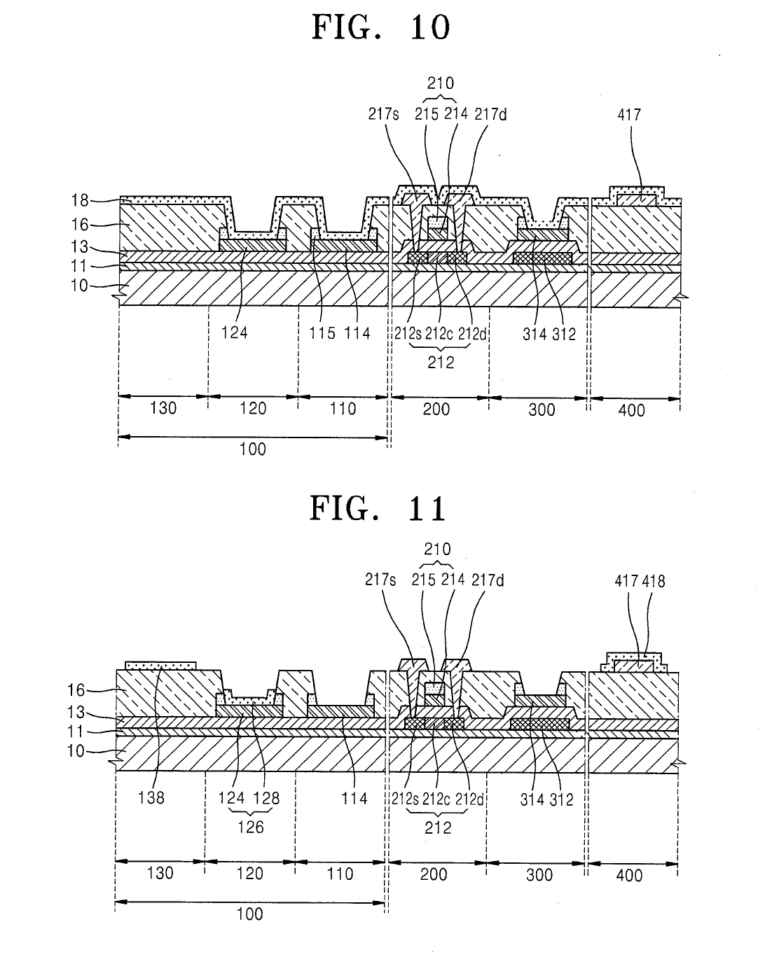

Next, as illustrated in FIG. 10, a fourth conductive layer 18 is formed on the first substrate 10.

The fourth conductive layer 18 may include at least one transparent material selected from the group consisting of ITO, IZO, ZnO, AZO, GIZO, and In₂O₃. The fourth conductive layer 18 may be patterned into the third pixel electrode 138, the upper pixel electrode 128, and the upper pad electrode 418. When the organic light-emitting display device 1 is a bottom emission type organic light-emitting display device that emits light toward the first substrate 10, the first pixel electrode 114 is formed as a transparent electrode. Thus, the first conductive layer 14 to be formed into the first pixel electrode 114 may be formed of TCO.

Next, as illustrated in FIG. 11, the upper pixel electrode 128, the upper pad electrode 418, and the third pixel electrode 138 are formed.

In more detail, the fourth conductive layer 18 formed on the first substrate 10 may be patterned via a mask process using a fifth mask (not shown). By doing so, in the emission region 130 for emitting a red color, the third pixel electrode 138 is formed on the second insulating layer 16, and in the emission region 120 for emitting a green color, the upper pixel electrode 128 is formed on the lower pixel electrode 124. In this manner, in the emission region 130 for emitting a red color (hereinafter, the red-color emission region 130) having a long light wavelength, the third pixel electrode 138 is formed on the second insulating layer 16 including an inorganic material so that a long optical path is formed. On the other hand, in the emission region 110 for emitting a blue color (hereinafter, the blue-color emission region 110) having a short light wavelength, only the first pixel electrode 114 is formed so that a short optical path is formed. In the emission region 120 for emitting a green color (hereinafter, the green-color emission region 120) having a medium light wavelength between the red color and the blue color, the second pixel electrode 126 including the lower pixel electrode 124, which has the same thickness and is formed from the same layer as the first pixel electrode 114, and the second pixel electrode 126, which has the same thickness and is formed from the same layer as the third pixel electrode 138, is formed. Thus, an optical path having the medium light wavelength between the red color and the blue color is formed in the emission region 120. Therefore, the organic light-emitting display device 1 has the optical paths having respectively different lengths for sub-pixels, according to color wavelengths, so that a luminescent efficiency may be maximized.

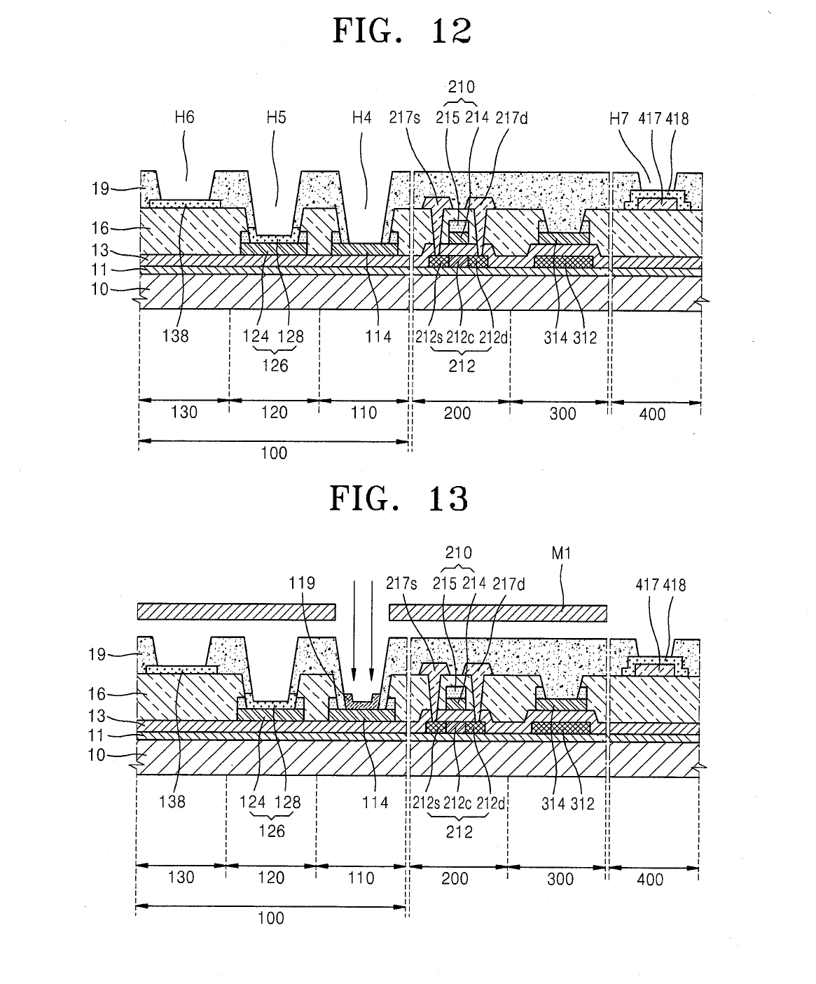

Next, as illustrated in FIG. 12, the PDL 19 is formed on the first substrate 10.

In more detail, a third insulating layer 19 may be deposited on the first substrate 10 of FIG. 11. Here, the third insulating layer 19 may be formed of at least one organic insulating material selected from the group consisting of polyimide, polyamide, acryl resin, benzocyclobutene, and phenol resin, by using a spin coating method or the like. The third insulating layer 19 may be formed of not only the organic insulating material but also formed of an inorganic insulating material selected from the group consisting of SiO₂, SiNₓ, Al₂O₃, CuOx, Tb₄O₇, Y₂O₃, Nb₂O₅, and Pr₂O₃. Alternatively, the third insulating layer 19 may have a multi-layer structure in which the organic insulating material and the inorganic insulating material alternate with each other.

Via a mask process using a sixth mask (not shown), the third insulating layer 19 may be patterned to form openings H4, H5, and H6 that expose center regions of the first, second, and third pixel electrodes 114, 126, and 138, respectively, so that the third insulating layer 19 defines emission regions. Also, the third insulating layer 19 may be patterned to form an opening H7 that exposes the upper pad electrode 418. However, aspects of the present invention are not limited thereto, and for example, the third insulating layer 19 may not be deposited in the pad region 400.

As described above, according to the present embodiment, a total of 6 mask processes are performed to sequentially form pixel electrodes on the first substrate 10. Hereinafter, a process of forming an intermediate layer (not shown) for emitting red, green, and blue colors in the emission region 100 of sub-pixels will be described.

The intermediate layer includes a common layer and an emission layer (EML). The common layer is commonly deposited on the sub-pixels and may have a structure in which a hole transport layer (HTL), a hole injection layer (HIL), an electron transport layer (ETL), an electron injection layer (EIL) or the like are singularly or multiply stacked. Because the common layer is commonly formed regardless of the sub-pixels, the common layer may be deposited without using a mask such as a fine metal mask (FMM), a slit, or the like.

The EML emits light of a red color, a green color, or a blue color. The EML may be formed by using, for example, a small molecule organic material or a polymer organic material. When the EML is formed of a small molecule organic material, an HTL and an HIL may be stacked below the EML toward the first pixel electrode 114, and an ETL and an EIL may be stacked on the EML toward the opposite electrode 150 (refer to FIG. 2). In addition to these layers, various layers may be stacked on or below the EML according to design considerations. Here, the EML may be formed by using one of various organic materials including copper phthalocyanine (CuPc), N,N′-Di(naphthalene-1-yl)-N,N′-diphenyl-benzidine (NPB), tris-8-hydroxyquinoline aluminum)(Alq3), or the like.

When the EML is formed of a polymer organic material, only an HTL may be stacked on the EML toward the first pixel electrode 114. The HTL may be formed of poly(3,4-ethylenedioxythiophene) (PEDOT) or polyaniline (PANI), and formed on the first pixel electrode 114 by using, for example, an inkjet printing method or a spin coating method. Here, the EML may be formed of a polymer organic material including polyphenylene vinylene (PPV), polyfluorene, or the like by using a common method such as an inkjet printing method, a spin coating method or a thermal transfer method using laser, and may form a color pattern.

In the EML, different layers are deposited according to different sub-pixels, respectively. Thus, a red-color EML 139 is formed in the red-color emission region 130, a green-color EML 129 is formed in the green-color emission region 120, and a blue-color EML 119 is formed in the blue-color emission region 110. Therefore, the EML may be formed via three deposition processes. For example, in the first deposition process, the blue-color EML 119 may be formed in the blue-color emission region 110 while the red-color emission region 130 and the green-color emission region 120 are blocked. In the second deposition process, the green-color EML 129 may be formed in the green-color emission region 120 while the red-color emission region 130 and the blue-color emission region 110 are blocked. In the third deposition process, the red-color EML 139 may be formed in the red-color emission region 130 while the green-color emission region 120 and the blue-color emission region 110 are blocked. However, an order of forming EMLs of different colors is not limited to the aforementioned order.

Referring to FIG. 13, the blue-color EML 119 is deposited on a top surface of the first pixel electrode 114 exposed via the opening H4 of the PDL 19. Here, the blue-color EML 119 may be formed in a manner such that an organic material is deposited via a penetration slit of an FMM M1, and the rest of the portions, except for the blue-color emission region 110, are blocked.

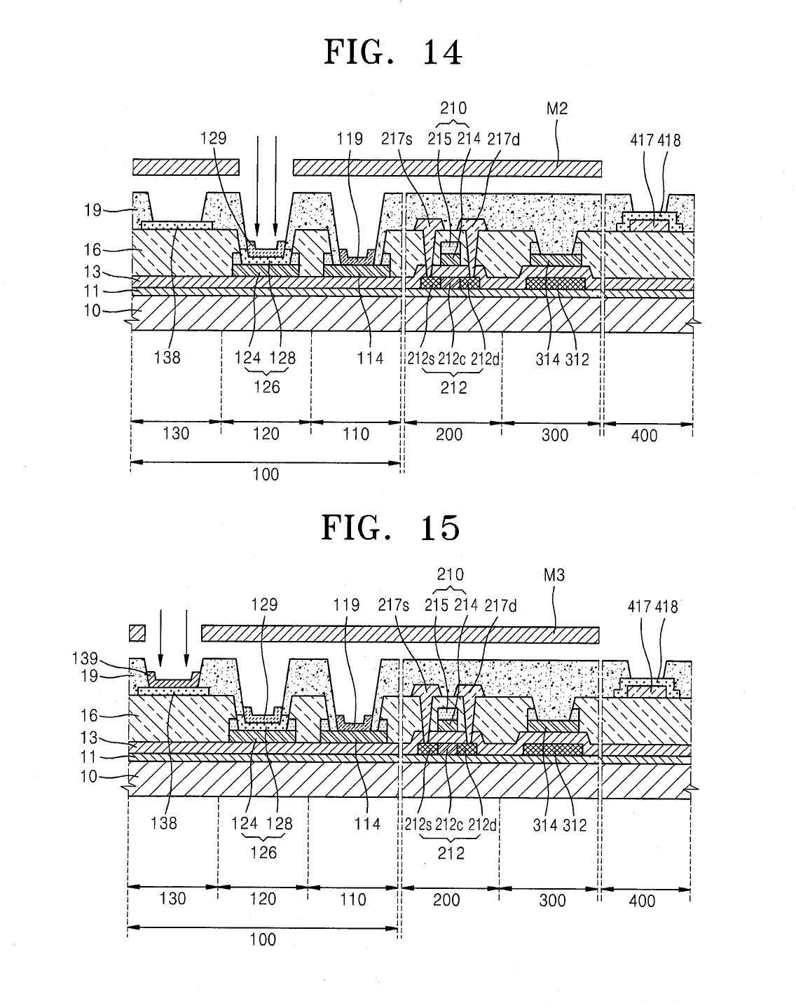

Similarly, referring to FIG. 14, the green-color EML 129 is deposited on a top surface of the second pixel electrode 126 exposed via the opening H5 of the PDL 19. Here, the green-color EML 129 may be formed in a manner such that an organic material is deposited via a penetration slit of an FMM M2, and the rest of the portions, except for the green-color emission region 120, are blocked.

Referring to FIG. 15, the red-color EML 139 is deposited on a top surface of the third pixel electrode 138 exposed via the opening H6 of the PDL 19. Here, the red-color EML 139 may be formed in a manner such that an organic material is deposited via a penetration slit of an FMM M3, and the rest of the portions, except for the red-color emission region 130, are blocked.

Lastly, the opposite electrode 150 (refer to FIG. 2) may be commonly formed on an entire surface of the first substrate 10 on which the intermediate layer is formed. In the organic light-emitting display device 1 according to the present embodiment, a pixel electrode may function as an anode electrode, and the opposite electrode 150 (refer to FIG. 2) may function as a cathode electrode. However, polarities of the electrodes may be switched.

When the organic light-emitting display device 1 is a bottom emission type organic light-emitting display device in which an image is realized toward the first substrate 10, pixel electrodes are formed as a transparent electrode, and the opposite electrode 150 (refer to FIG. 2) is formed as a reflective electrode. Here, the reflective electrode may be thinly formed by using a metal material having a small work function, such as Ag, Mg, Al, Pt, Pd, Au, Ni, Nd, Ir, Cr, Li, Ca, LiF/Ca, LiF/Al, or compound of any of these.

In the aforementioned mask processes to form the organic light-emitting display device 1, stacked layers may be removed by dry etching or wet etching.

The organic light-emitting display device 1 according to the present embodiment is manufactured by a total of 6 mask processes and the three deposition processes using the FMM, so that a luminescent efficiency of the organic light-emitting display device 1 is improved (e.g., maximized) in a manner that the organic light-emitting devices have differential structures according to the sub-pixels, without an increase in the number of manufacturing processes.

According to the related art, separate mask processes or deposition processes are added to increase a luminescent efficiency of an organic light-emitting display device. In more detail, a total of 5 or 6 mask processes are used to form a substrate through a pixel electrode, and 5 deposition processes using an FMM are added to differentially form organic light-emitting devices. Thus, a total of 10 or 11 processes are performed to realize the organic light-emitting devices having different structures according to sub-pixels, which increase a luminescent efficiency of the organic light-emitting display device.

However, according to the one or more embodiments of the present invention, a process of forming the upper pad electrode 418, and a process of forming the third pixel electrode 138 and the upper pixel electrode 128 are concurrently (or simultaneously) performed so that, before the intermediate layer including the EML is formed, the organic light-emitting devices that increase a luminescent efficiency of the organic light-emitting display device are already realized. Thus, only a small number of deposition processes is used to deposit the red, green, and blue-color EMLs by using a reduced (e.g., a minimum) number of FMMs, without additional deposition processes using an FMM.

While the aforementioned embodiments are described with reference to an organic light-emitting display device, aspects of the present invention are not limited thereto, and may be applied to various display devices including a liquid crystal display (LCD) device and the like.

Also, for convenience of description, drawings related to the aforementioned embodiments illustrate only one TFT and one capacitor, but aspects of the present invention are not limited thereto, and a plurality of TFTs and a plurality of capacitors may be included, provided that they do not increase the number of mask processes.

According to the one or more embodiments of the present invention, a manufacturing procedure of an organic light-emitting display device is improved so that reliability of the organic light-emitting display device is increased. Also, because pixel electrodes that respectively match with emission colors of sub-pixels are arranged, an emission efficiency is improved.

While the present invention has been particularly shown and described with reference to exemplary embodiments thereof, it will be understood by those of ordinary skill in the art that various changes in form and details may be made therein without departing from the spirit and scope of the present invention as defined by the following claims and their equivalents.

What is claimed is:

1. An organic light-emitting display device comprising:
a thin film transistor (TFT) comprising:
an active layer on a substrate;
a gate electrode insulated from the active layer and sequentially comprising a lower gate electrode and an upper gate electrode; and
a source electrode and a drain electrode insulated from the gate electrode by an interlayer insulating layer, which is on the gate electrode, and contacting the active layer;
a pad electrode comprising:
a lower pad electrode on the interlayer insulating layer and on the same layer as the source electrode and the drain electrode; and
an upper pad electrode on the lower pad electrode and electrically coupled to the TFT; and
an organic light-emitting device electrically coupled to the TFT and comprising:
a first organic light-emitting device in a first sub-pixel;
a second organic light-emitting device in a second sub-pixel; and
a third organic light-emitting device in a third sub-pixel,
wherein the first organic light-emitting device sequentially comprises:
a first pixel electrode on the same layer as the lower gate electrode of the gate electrode;
a first intermediate layer configured to emit light having a short wavelength; and
an opposite electrode,
wherein the second organic light-emitting device sequentially comprises:
a second pixel electrode, which comprises a lower pixel electrode on the same layer as the lower gate electrode; and an upper pixel electrode on the same layer as the lower pad electrode;
a second intermediate layer configured to emit light having a medium wavelength; and
the opposite electrode, and
wherein the third organic light-emitting device sequentially comprises:
a third pixel electrode on the interlayer insulating layer and on the same layer as the lower pad electrode;
a third intermediate layer configured to emit light having a long wavelength; and
the opposite electrode.

2. The organic light-emitting display device of claim 1, wherein the lower gate electrode, the first pixel electrode, and the lower pixel electrode each comprise a transparent conductive oxide (TCO).

3. The organic light-emitting display device of claim 1, wherein the upper pad electrode, the upper pixel electrode, and the third pixel electrode each comprise a transparent conductive oxide (TOO).

4. The organic light-emitting display device of claim 1, wherein the first intermediate layer is configured to emit blue light, the second intermediate layer is configured to emit green light, and the third intermediate layer is configured to emit red light.

5. The organic light-emitting display device of claim 1, wherein a distance between the substrate and the third intermediate layer is greater than a distance between the substrate and the first intermediate layer, or a distance between the substrate and the second intermediate layer.

6. The organic light-emitting display device of claim 1, wherein the interlayer insulating layer comprises an inorganic insulating material.

7. The organic light-emitting display device of claim 1, wherein the source electrode, the drain electrode, and the lower pad electrode each comprise a low-resistance metal material.

8. The organic light-emitting display device of claim 1,
further comprising a gate insulating layer between the active layer and the gate electrode, and
wherein the first organic light emitting device, the second light-emitting device, and the third organic light-emitting device are on the gate insulating layer.

9. The organic light-emitting display device of claim 1,
further comprising a pixel-defining layer (PDL) that covers the TFT and the pad electrode, and
wherein the PDL covers sides of the pad electrode and exposes at least a center region of the pad electrode.

10. The organic light-emitting display device of claim 1,
further comprising a capacitor that comprises:
a lower capacitor electrode on the same layer as the active layer; and
an upper capacitor electrode on the same layer as the lower gate electrode, and electrically coupled to the TFT.

11. A method of manufacturing an organic light-emitting display device, the method comprising:
a first mask process of forming an active layer of a thin film transistor (TFT) on a substrate;
a second mask process of forming a gate electrode comprising a lower gate electrode and an upper gate electrode, a first electrode pattern to form a first pixel electrode, and a second electrode pattern to form a second pixel electrode on the active layer;
a third mask process of forming an interlayer insulating layer that comprises contact holes that expose portions of the active layer, and openings that expose portions of the first electrode pattern and the second electrode pattern;
a fourth mask process of forming a source electrode and a drain electrode that contact the active layer via the contact holes, the first pixel electrode, a lower pixel electrode, and a lower pad electrode;
a fifth mask process of forming an upper pixel electrode on the lower pixel electrode, forming an upper pad electrode on the lower pad electrode, and forming a third pixel electrode; and
a sixth mask process of forming a pixel-defining layer (PDL) that exposes at least portions of the first pixel electrode, the upper pixel electrode, and the third pixel electrode.

12. The method of claim 11, wherein the second mask process comprises:
sequentially stacking a first insulating layer, a first conductive layer, and a second conductive layer on the active layer;
patterning the first conductive layer and the second conductive layer to form a gate electrode that comprises:
a lower gate electrode formed of the first conductive layer; and
an upper gate electrode formed of the second conductive layer; and
patterning the first conductive layer and the second conductive layer to form the first electrode pattern and the second electrode pattern.

13. The method of claim 11, further comprising forming a source region and a drain region by doping the active layer with an impurity after the second mask process.

14. The method of claim 11, wherein the third mask process comprises:
forming a second insulating layer on the gate electrode, the first electrode pattern, and the second electrode pattern;
patterning the first insulating layer and the second insulating layer to form the contact holes that expose the portions of the active layer; and
patterning the second insulating layer to form the openings that expose the portions of the first electrode pattern and the second electrode pattern.

15. The method of claim 11, wherein the fourth mask process comprises:
forming a third conductive layer on the interlayer insulating layer;
patterning the third conductive layer to form the source electrode and a drain electrode that contact the active layer via the contact holes, and the lower pad electrode;
forming the first pixel electrode by removing a second conductive layer comprised in the first electrode pattern; and
forming the lower pixel electrode by removing a second conductive layer comprised in the second electrode pattern.

16. The method of claim 15,
wherein the first mask process further comprises forming a lower capacitor electrode on the same layer as the active layer on the substrate,
wherein the second mask process further comprises forming a third electrode pattern to form an upper capacitor electrode on the lower capacitor electrode, and
wherein the fourth mask process further comprises forming the upper capacitor electrode by removing the second conductive layer comprised in the third electrode pattern.

17. The method of claim 11, further comprising:
forming a fourth conductive layer on an entire surface of the substrate; and
patterning the fourth conductive layer to form the upper pixel electrode on the lower pixel electrode, to form the upper pad electrode on the lower pad electrode, and to form the third pixel electrode.

18. The method of claim 11, wherein the fifth mask process comprises:
forming a third insulating layer on an entire surface of the substrate; and
patterning the third insulating layer to form the PDL that covers sides of the first pixel electrode, the upper pixel electrode, and the third pixel electrode, and exposes at least portions of the first pixel electrode, the upper pixel electrode, and the third pixel electrode.

19. The method of claim 11, further comprising:
forming a first intermediate layer for emitting blue light on the exposed first pixel electrode;
forming a second intermediate layer for emitting green light on the exposed second pixel electrode; and
forming a third intermediate layer for emitting red light on the exposed third pixel electrode.

20. The method of claim 19, further comprising forming an opposite electrode on an entire surface of the substrate to cover the first intermediate layer, the second intermediate layer, and the third intermediate layer.
